(19) United States
(12) Patent Application Publication
(10) Pub. No.: US 2024/0414989 A1
(43) Pub. Date: Dec. 12, 2024

(54) DISPLAY SUBSTRATE AND MANUFACTURING METHOD THEREFOR, AND DISPLAY DEVICE

(71) Applicants: Yunnan Invensight Optoelectronics Technology Co., Ltd., Kunming, Yunnan (CN); BOE Technology Group Co., Ltd., Beijing (CN)

(72) Inventors: Yunhao ZHANG, Beijing (CN); Weiliang BU, Beijing (CN); Hongtao YU, Beijing (CN); Lingang WEN, Beijing (CN); Cao WU, Beijing (CN); Kuanta HUANG, Beijing (CN); Xiaochuan CHEN, Beijing (CN); Hui WANG, Beijing (CN)

(21) Appl. No.: 18/702,820

(22) PCT Filed: Apr. 26, 2023
(86) PCT No.: PCT/CN2023/090942

§ 371 Date: Apr. 19, 2024

(30) Foreign Application Priority Data
Jun. 10, 2022 (CN) 202210656610.1

(51) Int. Cl. H10K 59/80; H10K 59/12; H10K 59/122

(52) U.S. Cl. CPC H10K 59/879; H10K 59/1201; H10K 59/122

(57) ABSTRACT

A display substrate and a manufacturing method therefor, and a display device. The display substrate comprises a display structure layer (100), a packaging structure layer (200) provided on the display structure layer (100), and a color film structure layer (300) provided on the side of the packaging structure layer (200) farthest from the display structure layer, wherein the packaging structure layer (200) at least comprises a light extraction structure (43) used for improving the light emitting efficiency.

### CROSS-REFERENCE TO RELATED APPLICATIONS

The present application is a U.S. National Phase Entry of International Application No. PCT/CN2023/090942, having an international filing date of Apr. 26, 2023, which claims priority to Chinese Patent Application No. 202210656610.1 filed to the CNIPA on Jun. 10, 2022 and entitled “Display Substrate and Manufacturing Method Therefor, and Display Device”. The entire contents of above-identified applications are hereby incorporated into the present application by reference.

### TECHNICAL FIELD

The present disclosure relates to, but is not limited to, the field of display technology, and in particular to a display substrate and a manufacturing method therefor, and a display device.

### BACKGROUND

Micro organic light-emitting diodes (Micro OLEDs) are micro displays developed in recent years, among which there are silicon-based OLEDs. The silicon-based OLEDs can not only realize active addressing of pixels, but also can realize manufacturing of structures such as pixel driving circuits on a silicon-based substrate, which is conducive to reduce system volume and realize lightweight. Silicon-based OLEDs are manufactured using mature Complementary Metal Oxide Semiconductor (CMOS) integrated circuit process. Due to their advantages such as small size, high Pixels Per Inch (PPI), and high refresh rate, they are widely used in near-to-eye display fields of Virtual Reality (VR) or Augmented Reality (AR).

### SUMMARY

The following is a summary of subject matters described herein in detail. This summary is not intended to limit the protection scope of claims.

In one aspect, the present disclosure provides a display substrate including a display structure layer, an encapsulation structure layer provided on the display structure layer, and a color film structure layer provided on a side of the encapsulation structure layer away from the display structure layer. The encapsulation structure layer at least includes a light extraction structure for improving light emitting efficiency.

In an exemplary embodiment, the display structure layer at least includes a base substrate, a driving circuit layer provided on the base substrate, and a light emitting structure layer provided on a side of the driving circuit layer away from the base substrate. The light emitting structure layer at least includes an anode and a pixel definition layer provided on a side of the anode away from the base substrate. A pixel opening is provided on the pixel definition layer, the pixel opening exposes the anode, and an orthographic projection of the pixel opening on the base substrate is within a range of an orthographic projection of the light extraction structure on the base substrate.

In an exemplary embodiment, a light extraction area of the light extraction structure is 1.4 times to 1.6 times an opening area of the pixel opening. The light extraction area is an area of an orthographic projection of the light extraction structure on the display substrate, and the opening area is an area of an orthographic projection of the pixel opening on the display substrate.

In an exemplary embodiment, the encapsulation structure layer at least includes a first sublayer, a second sublayer provided on a side of the first sublayer away from the display structure layer, a plurality of light extraction structures provided on a side of the second sublayer away from the display structure layer, and a cover layer for covering the plurality of light extraction structures. A refractive index of the light extraction structure is greater than a refractive index of the cover layer.

In an exemplary embodiment, a material for the first sublayer includes silicon nitride, and a thickness of the first sublayer is 0.8 μm to 1.2 μm.

In an exemplary embodiment, a material for the second sublayer includes alumina, and a thickness of the second sublayer is 0.03 μm to 0.05 μm.

In an exemplary embodiment, the refractive index of the light extraction structure is greater than 1.92, and the refractive index of the cover layer is less than or equal to 1.5.

In an exemplary embodiment, a transmittance of the cover layer is greater than 95% in a wavelength band from 380 nm to 980 nm.

In an exemplary embodiment, the light extraction structure includes any one or more of a plano-convex convex lens, a prism with a trapezoidal cross-section, or a prism with a triangular cross-section.

In an exemplary embodiment, on a plane parallel to the display substrate, a light extraction width of the light extraction structure is 3.2 μm to 3.4 μm, and the light extraction width is a maximum distance between any two points on an edge of the light extraction structure.

In an exemplary embodiment, a light extraction height of the light extraction structure is 2.0 μm to 2.2 μm, and the light extraction height is a maximum distance between a surface on a side of the light extraction structure away from the display structure layer and a surface on a side of the light extraction structure close to the display structure layer.

In an exemplary embodiment, the cover layer is an organic material, and a difference between a thickness of the cover layer and the light extraction height is greater than or equal to 0.2 μm.

In an exemplary embodiment, the color film structure layer at least includes a plurality of light filter layers and black matrices provided between the light filter layers, and an orthographic projection of the light extraction structure on a display substrate plane is within a range of an orthographic projection of a light filter layer on the display substrate plane.

In another aspect, the present disclosure further provides a display device including the display substrate described above.

In yet another aspect, the present disclosure further provides a method for manufacturing a display substrate including:
forming a display structure layer;
forming an encapsulation structure layer on the display structure layer, the encapsulation structure layer at least including a light extraction structure for improving light emitting efficiency; and
forming a color film structure layer on the encapsulation structure layer.

Other aspects of the present disclosure may be comprehended after the drawings and the detailed descriptions are read and understood.

### BRIEF DESCRIPTION OF DRAWINGS

Accompany drawings are used to provide further understanding of technical solution of the present disclosure, and form a part of the specification. The accompany drawings and embodiments of the present disclosure are adopted to explain the technical solution of the present disclosure, and do not form limitations on the technical solution of the present disclosure.

FIG. 1 is a schematic diagram of a structure of a silicon-based OLED display device;

FIG. 2 is a schematic diagram of a planar structure of a silicon-based OLED display device;

FIG. 3 is a schematic diagram of an equivalent circuit of a pixel driving circuit;

FIG. 4 is a schematic diagram of a cross-sectional structure of a display substrate according to an exemplary embodiment of the present disclosure;

FIG. 5 is a schematic diagram of a cross-sectional structure of another display substrate according to an exemplary embodiment of the present disclosure;

FIG. 6 is a schematic diagram of a cross-sectional structure of yet another display substrate according to an exemplary embodiment of the present disclosure;

FIG. 7 is a schematic diagram of a cross-sectional structure of yet another display substrate according to an exemplary embodiment of the present disclosure;

FIG. 8 is a schematic diagram after a pattern of a driving circuit layer is formed according to an exemplary embodiment of the present disclosure;

FIG. 9 is a schematic diagram after a pattern of an anode conductive layer is formed according to an embodiment of the present disclosure;

FIG. 10 is a schematic diagram after a pattern of a pixel definition layer is formed according to an exemplary embodiment of the present disclosure;

FIG. 11 is a schematic diagram after a pattern of an organic light emitting layer is formed according to an exemplary embodiment of the present disclosure;

FIG. 12 is a schematic diagram after a pattern of a cathode is formed according to an exemplary embodiment of the present disclosure;

FIG. 13 is a schematic diagram after patterns of a first sublayer and a second sublayer are formed according to an exemplary embodiment of the present disclosure;

FIG. 14 is a schematic diagram after a pattern of a photoresist is formed according to an exemplary embodiment of the present disclosure;

FIG. 15 is a schematic diagram of after a photoresist is baked according to an exemplary embodiment of the present disclosure;

FIG. 16 is a schematic diagram after a pattern of a light extraction structure is formed according to an exemplary embodiment of the present disclosure;

FIG. 17 is a schematic diagram after a pattern of a cover layer is formed according to an exemplary embodiment of the present disclosure; and

FIG. 18 is a schematic diagram after a pattern of a color film structure layer is formed according to an exemplary embodiment of the present disclosure.

Reference signs are described as follows.

| | | |
|---|---|---|
| 10-base substrate; | 11-first insulation layer; | 12-second insulation layer; |
| 13-third insulation layer; | 14-fourth insulation layer; | 20-driving circuit layer; |
| 30-light emitting structure layer; | 31-anode; | 32-pixel definition layer; |
| 33-organic light emitting layer; | 34-cathode; | 35-pixel opening; |
| 41-first sublayer; | 42-second sublayer; | 43-light extraction structure; |
| 44-cover layer; | 45-inorganic material film; | 46-photoresist column; |
| 47-photoresist spherical crown body; | 51-black matrix; | 52-light filter layer; |
| 100-display structure layer; | 200-encapsulation structure layer; and | 300-color film structure layer. |

### DETAILED DESCRIPTION

Embodiments of the present disclosure will be described in detail hereinafter with reference to the drawings. It is to be noted that embodiments may be implemented in multiple different forms. Those of ordinary skills in the art can easily understand such a fact that embodiments and contents may be transformed into various forms without departing from the purpose and scope of the present disclosure. Therefore, the present disclosure should not be explained as being limited to the contents recorded in the following embodiments only. The embodiments and features in the embodiments of the present disclosure may be randomly combined with each other if there is no conflict. In order to keep following description of the embodiments of the present disclosure clear and concise, detailed description of part of known functions and known components are omitted in the present disclosure. The drawings in the embodiments of the present disclosure relate only to the structures involved in the embodiments of the present disclosure, and other structures may be described with reference to conventional designs.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings.

Ordinal numerals, such as “first”, “second” and “third”, in the specification are set not to limit the quantity but only to avoid confusion between composition elements.

In the present disclosure, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to the drawings. They are only for easily and simply describing the present specification, but do not indicate or imply that involved devices or elements are required to have specific orientations and be structured and operated with the specific orientations, and thus should not be understood as limitations on the present disclosure. The positional relationships between the constituent elements may be appropriately changed according to a direction according to which each constituent element is described. Therefore, appropriate replacements based on situations are allowed, which is not limited to the expressions in the specification.

In the present disclosure, unless otherwise specified and defined, terms “mount”, “couple”, and “connect” should be understood in a broad sense. For example, a connection may be fixed connection, or a detachable connection, or an integral connection; it may be a mechanical connection or an electrical connection; it may be a direct connection, or an indirect connection through middleware, or internal communication inside two elements. Those of ordinary skills in the art may understand specific meanings of the above terms in the present disclosure according to specific situations.

In the present disclosure, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the present disclosure, the channel region refers to a region through which a current mainly flows.

In the present disclosure, a first electrode may be a drain electrode, and a second electrode may be a source electrode. Or, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the present disclosure.

In the present disclosure, “electrical connection” includes connection of composition elements through an element with a certain electrical action. An “element with a certain electrical action” is not particularly limited as long as electrical signals between the connected constituent elements may be sent and received. Examples of the “element with the certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined strictly, and numerical values within a range of process and measurement errors are allowed.

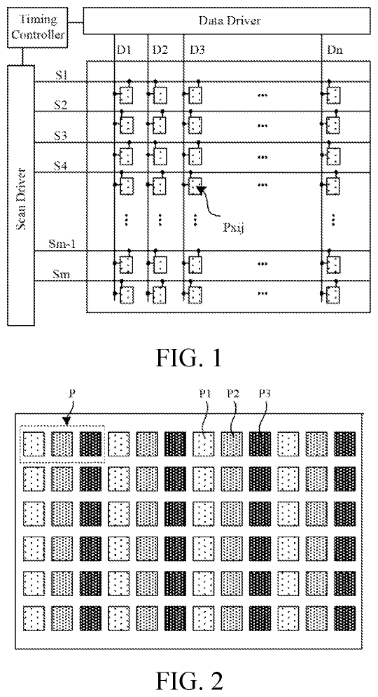

FIG. 1 is a schematic diagram of a structure of a silicon-based OLED display device. As shown in FIG. 1, the silicon-based OLED display device may include a timing controller, a data signal driver, a scan signal driver and a pixel array. The pixel array may include a plurality of scan signal lines (S1 to Sm), a plurality of data signal lines (D1 to Dn) and a plurality of sub-pixels Pxij. In an exemplary embodiment, the timing controller may provide the data signal driver with a gray scale value and a control signal which are suitable for a specification of the data signal driver, and provide the scan signal driver with a clock signal, a scan start signal, etc., which are suitable for a specification of the scan signal driver. The data signal driver may generate data voltages to be provided to data signal lines D1, D2, D3, . . . , and Dn using the gray scale value and the control signal received from the timing controller. For example, the data signal driver may sample gray scale values using the clock signal and apply the data voltages corresponding to the gray scale values to the data signal lines DI to Dn by taking a row of sub-pixels as a unit, wherein n may be a natural number. The scan signal driver may generate scan signals to be provided to scan signal lines S1, S2, S3, . . . , and Sm by receiving a clock signal, a scan start signal, and the like from the timing controller. For example, the scan signal driver may sequentially provide scan signals with turning-on-level pulses to the scan signal lines S1 to Sm. For example, the scan signal driver may be constructed in a form of a shift register, and generate the scan signals in a mode of sequentially transmitting the scan start signal provided in a form of turning-on-level pulses to a next-stage circuit under controlling of the clock signal, wherein m may be a natural number. An array of sub-pixels may include a plurality of sub-pixels Pxij. Each sub-pixel Pxij may be connected to a corresponding data signal line and a corresponding scan signal line, and i and j may be natural numbers. The sub-pixel Pxij may refer to a sub-pixel of which a transistor is connected to an i-th scan signal line and connected to a j-th data signal line.

FIG. 2 is a schematic diagram of a planar structure of a silicon-based OLED display device. As shown in FIG. 2, the display device may include a plurality of pixel units P arranged in a matrix. At least one of the plurality of pixel units P may include a first sub-pixel P1 emitting light of a first color, a second sub-pixel P2 emitting light of a second color, and a third sub-pixel P3 emitting light of a third color. The three sub-pixels each include a pixel driving circuit and a light emitting device, and the pixel driving circuit in the sub-pixel is connected to a scan signal line and a data signal line, respectively, and the pixel driving circuit is configured to receive a data voltage transmitted by the data signal line under the control of the scan signal line and output a corresponding current to the light emitting device for display. The light emitting device for display in the sub-pixel is connected to the pixel driving circuit of the sub-pixel where the light emitting device for display is located, and the light emitting device for display is configured to emit light with a corresponding brightness in response to the current outputted by the pixel driving circuit of the sub-pixel where the light emitting device for display is located.

In an exemplary embodiment, the first sub-pixel P1 may be a red sub-pixel emitting red (R) light, the second sub-pixel P2 may be a green sub-pixel emitting green (G) light, and the third sub-pixel P3 may be a blue sub-pixel emitting blue (B) light.

In an exemplary embodiment, the sub-pixels may be in a shape of any one or more of a triangle, a square, a rectangle, a rhombus, a trapezoid, a parallelogram, a pentagon, a hexagon and other polygons. The three sub-pixels may be arranged side by side horizontally, side by side vertically or in a shape of the Chinese character “ [symbol] ”, which is not limited here in the present disclosure.

In other possible embodiments, the pixel unit may include four sub-pixels, such as the red sub-pixel, the green sub-pixel, the blue sub-pixel, and a white (W) sub-pixel, the four sub-pixels may be arranged side by side horizontally, side by side vertically, or in a form of a square, which is not limited here in the present disclosure.

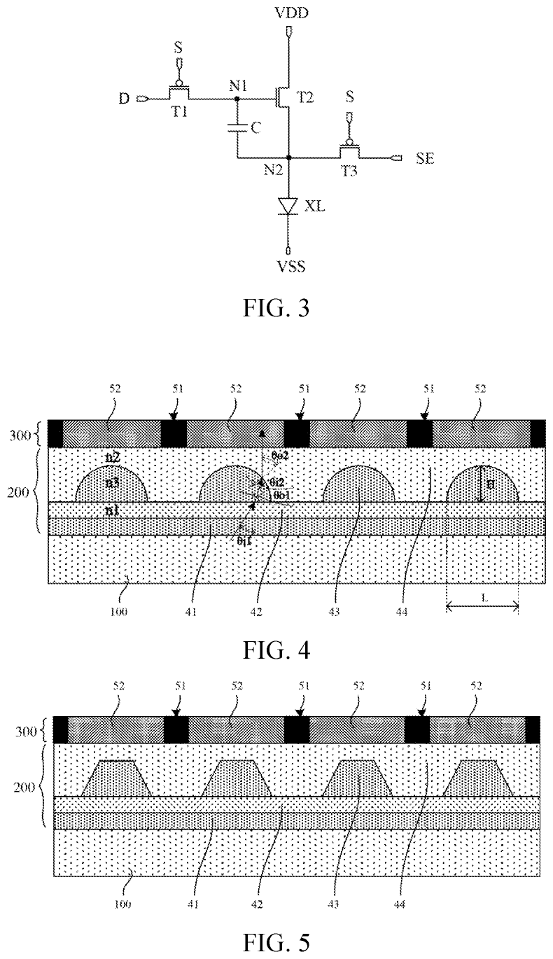

FIG. 3 is a diagram of an equivalent circuit of a pixel driving circuit. In an exemplary embodiment, the pixel driving circuit may be a 3TIC, 4TIC, 5TIC, 5T2C, 6TIC, 7TIC structure or the like. As shown in FIG. 3, the pixel driving circuit may be a 3TIC structure, including three transistors (a first transistor T1 to a third transistor T3) and one storage capacitor C. The pixel driving circuit is connected to five signal lines (a scan signal line S, a data signal line D, a compensation signal line SE, a first power supply line VDD and a second power supply line VSS), the first transistor T1 is a switching transistor, the second transistor T2 is a driving transistor, the third transistor T3 is a compensation transistor, and the first node N1 and the second node N2 are junction points indicating the electrical connections of related devices in the circuit diagram.

In an exemplary embodiment, a first end of the storage capacitor C is connected to the first node N1, and a second end of the storage capacitor C may be connected to the second node N2, or may be connected to a ground line (GND).

In an exemplary embodiment, a control electrode of the first transistor T1 is connected to the scan signal line S, a first electrode of the first transistor T1 is connected to the data signal line D, and a second electrode of the first transistor T1 is connected to the first node N1.

In an exemplary embodiment, a control electrode of the second transistor T2 is connected to the first node N1, a first electrode of the second transistor T2 is connected to the first power supply line VDD, and a second electrode of the second transistor T2 is connected to the second node N2.

In an exemplary embodiment, a control electrode of the third transistor T3 is connected to the scan signal line S, a first electrode of the third transistor T3 is connected to the compensation signal line SE, and a second electrode of the third transistor T3 is connected to the second node N2.

In an exemplary embodiment, a first electrode of a light emitting device XL is connected to the second node N2, and a second electrode of the light emitting device XL is connected to the second power supply line VSS.

In an exemplary embodiment, the first transistor T1 is configured to receive a data voltage transmitted by the data signal line D under the control of a signal of the scan signal line S, store the data voltage to the storage capacitor C, and supply the data voltage to the control electrode of the second transistor T2. The second transistor T2 is configured to generate a corresponding current at the second electrode under the control of a data signal received by the control electrode thereof. The second transistor T2 is configured to supply a signal of the first power supply line VDD to the second node N2 under the control of the third transistor T3 to drive the light emitting device for display XL to emit light. The third transistor T3 is configured to extract a threshold voltage Vth and a mobility of the second transistor T2 in response to compensation timing to compensate the threshold voltage Vth. The storage capacitor C is configured to store a potential of the control electrode of the second transistor T2, and the light emitting device XL is configured to emit light with a corresponding brightness in response to the current of the second electrode of the second transistor T2.

In an exemplary embodiment, the signal of the first power supply line VDD may be a high-level signal continuously provided, and a signal of the second power supply line VSS may be a low-level signal continuously provided.

In an exemplary embodiment, the first transistor T1, the second transistor T2 and the third transistor T3 may be P-type transistors. In another exemplary embodiment, the first transistor T1, the second transistor T2, and the third transistor T3 may be N-type transistors. Using transistors having the same type in the pixel driving circuit may simplify a process flow, reduce process difficulty of the display substrate, and improve a product yield. In yet another exemplary embodiment, the first transistor T1, the second transistor T2 and the third transistor T3 may include a P-type transistor and an N-type transistor. For example, the first transistor T1 and the third transistor T3 may be P-type metal oxide semiconductor transistors (PMOS), and the second transistor T2 may be an N-type metal oxide semiconductor transistor (NMOS).

In an exemplary embodiment, the light emitting device XL may be an organic light emitting diode (OLED), including a first electrode (anode), an organic light emitting layer and a second electrode (cathode) that are stacked.

An exemplary embodiment of the present disclosure provides a display substrate. The display substrate of the exemplary embodiment of the present disclosure may at least include a display structure layer, an encapsulation structure layer provided on the display structure layer, and a color film structure layer provided on a side of the encapsulation structure layer away from the display structure layer. The encapsulation structure layer at least includes a light extraction structure for improving light emitting efficiency.

In an exemplary embodiment, the display structure layer at least includes a base substrate, a driving circuit layer provided on the base substrate, and a light emitting structure layer provided on a side of the driving circuit layer away from the base substrate. The light emitting structure layer at least includes an anode and a pixel definition layer provided on a side of the anode away from the base substrate, a pixel opening is provided on the pixel definition layer, the pixel opening exposes the anode, and an orthographic projection of the pixel opening on the base substrate is within a range of an orthographic projection of the light extraction structure on the base substrate.

In an exemplary embodiment, a light extraction width of the light extraction structure is 1.4 times to 1.6 times an opening width of the pixel opening, the light extraction width is a maximum distance between any two points on an edge of the light extraction structure, and the opening width is a maximum distance between any two points on an edge of the pixel opening.

In an exemplary embodiment, the encapsulation structure layer at least includes a first sublayer, a second sublayer provided on a side of the first sublayer away from the display structure layer, a plurality of light extraction structures provided on a side of the second sublayer away from the display structure layer, and a cover layer for covering the plurality of light extraction structures. A refractive index of the light extraction structure is greater than a refractive index of the cover layer.

In an exemplary embodiment, the light extraction structure includes any one or more of a plano-convex convex lens, a prism with a trapezoidal cross-section, or a prism with a triangular cross-section.

FIG. 4 is a schematic diagram of a cross-sectional structure of a display substrate according to an exemplary embodiment of the present disclosure, which illustrates a structure of four sub-pixels. As shown in FIG. 4, on a plane perpendicular to the display substrate, the display substrate may include a display structure layer 100, an encapsulation structure layer 200 provided on the display structure layer 100, and a color film structure layer 300 provided on a side of the encapsulation structure layer 200 away from the display structure layer. In an exemplary embodiment, a plurality of light extraction structures are provided in the encapsulation structure layer 200 and the light extraction structures are configured to modulate light emitted from the display structure layer to effectively improve the light emitting efficiency.

In an exemplary embodiment, the display structure layer 100 may include a base substrate, a driving circuit layer provided on the base substrate, and a light emitting structure layer provided on a side of the driving circuit layer away from the base substrate. The base substrate may be a silicon base substrate (wafer), the driving circuit layer may at least include a plurality of driving circuits, and the light emitting structure layer may at least include a plurality of light emitting devices. The plurality of light emitting devices are correspondingly connected to the plurality of driving circuits, and the light emitting devices are configured to emit light with a corresponding brightness in response to a current outputted by the driving circuits of the sub-pixels where the light emitting devices are located.

In an exemplary embodiment, the driving circuit may at least include a storage capacitor and a plurality of transistors, the light emitting device may at least include an anode, an organic light emitting layer and a cathode, and the organic light emitting layer is provided between the anode and the cathode.

In an exemplary embodiment, the color film structure layer 300 may at least include a plurality of black matrices 51 and a plurality of light filter layers 52. The plurality of black matrices 51 and the plurality of light filter layers 52 may be provided on a side of the encapsulation structure layer 200 away from the display structure layer. The plurality of black matrices 51 may be provided at intervals, and light-transmitting openings are formed between adjacent black matrices 51. The plurality of light filter layers 52 may be provided at intervals and provided in the plurality of light-transmitting openings, respectively, to form an array of light filter layers separated by the black matrices 51. The black matrices 51 are provided between adjacent light filter layers 52. In an exemplary embodiment, the color film structure layer 300 is configured to reduce reflection of external light and replace a polarizer so as to effectively improve the transmittance, color saturation and bending resistance of the display substrate.

In an exemplary embodiment, the plurality of light filter layers 52 may include a red light filter layer that transmits red light, a green light filter layer that transmits green light, and a blue light filter layer that transmits blue light. The red light filter layer may be located in an region where the red sub-pixel (the first sub-pixel P1) is located, the green light filter layer may be located in an region where the green sub-pixel (the second sub-pixel P2) is located, and the blue light filter layer may be located in an region where the blue sub-pixel (the third sub-pixel P3) is located.

In an exemplary embodiment, the encapsulation structure layer 200 may include a first sublayer 41 provided on the display structure layer 100, a second sublayer 42 provided on a side of the first sublayer 41 away from the display structure layer, a plurality of light extraction structures 43 provided on a side of the second sublayer 42 away from the display structure layer, and a cover layer 44 for covering the plurality of light extraction structures 43. Positions of the plurality of light extraction structures 43 may have one-to-one correspondence to positions of the plurality of light filter layers 52, and a surface on a side of the cover layer 44 away from the display structure layer may be a planar surface.

In an exemplary embodiment, a material for the first sublayer 41 may be an inorganic material. For example, the material for the first sublayer 41 may be silicon nitride (SiNₓ).

In an exemplary embodiment, a thickness of the first sublayer 41 may be about 0.8 μm to 1.2 μm. For example, the thickness of the first sublayer 41 may be about 1.0 μm.

In an exemplary embodiment, a material for the second sublayer 42 may be an inorganic material. For example, the material for the second sublayer 42 may be alumina (Al₂O₃).

In an exemplary embodiment, a thickness of the second sublayer 42 may be about 0.03 μm to 0.05 μm. For example, the thickness of the second sublayer 42 may be about 0.05 μm.

In an exemplary embodiment, a material for the plurality of light extraction structures 43 may be an inorganic material. For example, the material for the plurality of light extraction structures 43 may be silicon nitride (SiNₓ).

In an exemplary embodiment, a refractive index of a light extraction structure 43 may be greater than 1.92. For example, the refractive index of the light extraction structure 43 may be about 2.0.

In an exemplary embodiment, a material for the cover layer 44 may be an organic material. For example, the material for the cover layer 44 may be an optical resin.

In an exemplary embodiment, a thickness of the cover layer 44 may be about 2.0 μm to 2.6 μm. For example, the thickness of the cover layer 44 may be about 2.3 μm.

In an exemplary embodiment, a refractive index of the cover layer 44 may be less than or equal to 1.5. For example, the refractive index of the cover layer 44 may be about 1.45.

In an exemplary embodiment, a transmittance of the cover layer 44 is greater than 95% in a wavelength band from 380 nm to 980 nm.

In an exemplary embodiment, the light extraction structure 43 may be a spherical crown body and form a plano-convex convex lens having a lower flat surface and an upper convex surface (i.e., the lower surface is flat and the upper surface is convex). The plurality of light extraction structures on the display substrate may be of a same type, so that light emitted from the sub-pixel is deflected toward a direction of a center of the sub-pixel so as to improve the light emitting efficiency of the sub-pixel. In an exemplary embodiment, the center of the sub-pixel may be a geometric center of the sub-pixel.

In an exemplary embodiment, an orthographic projection of at least one light extraction structure 43 on the display structure layer at least partially overlaps an orthographic projection of at least one light filter layer 52 on the display structure layer.

In an exemplary embodiment, the orthographic projection of the at least one light extraction structure 43 on the display structure layer may be within a range of the orthographic projection of the at least one light filter layer 52 on the display structure layer.

In an exemplary embodiment, the orthographic projection of the at least one light extraction structure 43 on the display structure layer may substantially coincide with the orthographic projection of the at least one light filter layer 52 on the display structure layer.

In an exemplary embodiment, an orthographic projection of a light extraction structure 43 on the display structure layer does not overlap an orthographic projection of a black matrix 51 on the display structure layer.

In the exemplary embodiment, taking the light extraction structure 43 being spherical crown body as an example, after light emitted from the light emitting device in the display structure layer 100 passes through the first sublayer 41 and the second sublayer 42, it is incident on an interface between the second sublayer 42 and the light extraction structure 43 at a first incident angle θi1, and enters the light extraction structure 43 at a first refraction angle θo1. After being transmitted in the light extraction structure 43, the light is incident on an interface between the light extraction structure 43 and the cover layer 44 at a second incident angle θi2, and enters the cover layer 44 at a second refraction angle θo2.

In an exemplary embodiment, the second sublayer 42 has a first refractive index n1, the cover layer 44 has a second refractive index n2, and the light extraction structure 43 has a third refractive index n3. The third refractive index n3≥the first refractive index n1, and the third refractive index n3>the second refractive index n2.

In an exemplary embodiment, according to refraction law: n1*Sin θi1=n3*Sin θo1, it may be seen that since the third refractive index n3≥the first refractive index n1, the first incident angle θi1 of the light incident on the light extraction structure 43 is greater than or equal to the first refractive angle θo1 of the light entering the light extraction structure 43, that is, the light entering the light extraction structure 43 is deflected toward the direction of the center of the sub-pixel relative to the incident light. The greater a difference between the first refractive index n1 and the third refractive index n3, the greater a degree of deflection of the light entering the light extraction structure 43 toward the center of the sub-pixel.

In an exemplary embodiment, according to refraction law: n3*Sin θi2=n2*Sin ηo2, it may be seen that since the third refractive index n3>the second refractive index n2, the second incident angle θi2 of the light incident on the cover layer 44 is less than the second refractive angle θo2 of the light entering the cover layer 44, that is, the light entering the cover layer 44 is deflected toward the direction of the center of the sub-pixel relative to the incident light. The greater a difference between the third refractive index n3 and the second refractive index n2, the greater a degree of deflection of the light entering the cover layer 44 toward the center of the sub-pixel.

In an exemplary embodiment, the light extraction structure 43 may have a light extraction height H which may be about 2.0 μm to 2.2 μm. For example, the light extraction height H may be about 2.1 μm.

In an exemplary embodiment, the light extraction height H of the light extraction structure 43 may be a maximum distance between a surface on a side of the light extraction structure 43 away from the display structure layer and a surface on a side of the light extraction structure 43 close to the display structure layer.

In an exemplary embodiment, on a plane parallel to the display substrate, a shape of the light extraction structure 43 may include any one or more of: a triangle, a square, a rectangle, a pentagon, a hexagon, a circle, and an ellipse.

In an exemplary embodiment, the light extraction structure 43 may have a light extraction width L which may be about 3.2 μm to 3.4 μm. For example, the light extraction width L may be about 3.2 μm.

In an exemplary embodiment, the light extraction width L of the light extraction structure 43 may be a maximum distance between any two points on an edge of the light extraction structure 43.

FIG. 5 is a schematic diagram of a cross-sectional structure of another display substrate according to an exemplary embodiment of the present disclosure, which illustrates a structure of four sub-pixels. As shown in FIG. 5, a main body structure of the display substrate of the present exemplary embodiment is substantially the same as the structure shown in FIG. 4 except that the light extraction structure of the present exemplary embodiment is a prism with a trapezoidal cross-section.

In an exemplary embodiment, the encapsulation structure layer 200 may include a first sublayer 41 provided on the display structure layer 100, a second sublayer 42 provided on a side of the first sublayer 41 away from the display structure layer, a plurality of light extraction structures 43 provided on a side of the second sublayer 42 away from the display structure layer, and a cover layer 44 for covering the plurality of light extraction structures 43. Positions of the plurality of light extraction structures 43 may have one-to-one correspondence to positions of the plurality of light filter layers 52. A light extraction structure 43 may be of a prismatic structure, and the plurality of light extraction structures on the display substrate may be of a same type. In a plane perpendicular to the display structure layer, a cross-sectional shape of the light extraction structure 43 may be trapezoidal to form a prism structure having a trapezoidal cross-section, so that light emitted from the sub-pixel is deflected toward a direction of a center of the sub-pixel to improve the light emitting efficiency of the sub-pixel.

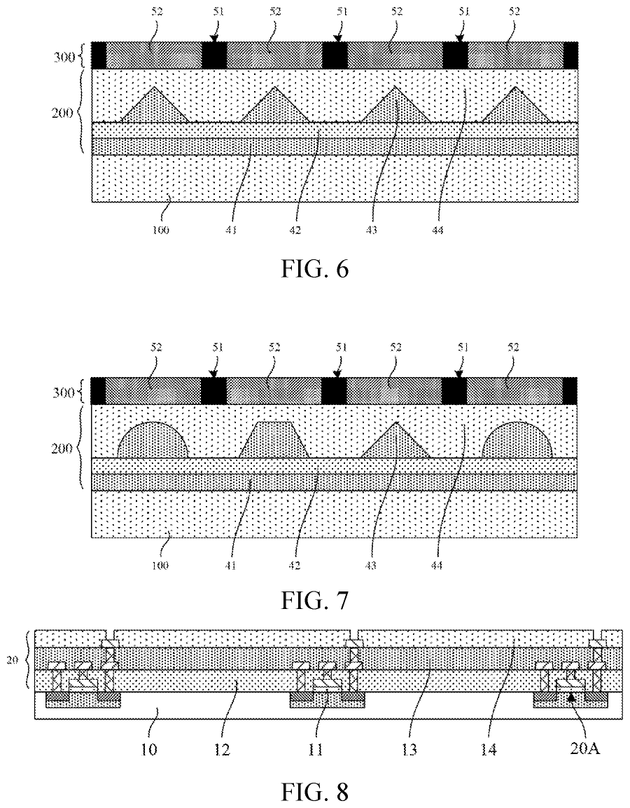

FIG. 6 is a schematic diagram of a cross-sectional structure of yet another display substrate according to an exemplary embodiment of the present disclosure, which illustrates a structure of four sub-pixels. As shown in FIG. 6, a main body structure of the display substrate of the present exemplary embodiment is substantially the same as the structure shown in FIG. 4 except that the light extraction structure of the present exemplary embodiment is a prism with a triangular cross-section.

In an exemplary embodiment, the encapsulation structure layer 200 may include a first sublayer 41 provided on the display structure layer 100, a second sublayer 42 provided on a side of the first sublayer 41 away from the display structure layer, a plurality of light extraction structures 43 provided on a side of the second sublayer 42 away from the display structure layer, and a cover layer 44 for covering the plurality of light extraction structures 43. Positions of the plurality of light extraction structures 43 may have one-to-one correspondence to positions of the plurality of light filter layers 52. A light extraction structure 43 may be of a pyramid structure, and the plurality of light extraction structures on the display substrate may be of a same type. In a plane perpendicular to the display structure layer, a cross-sectional shape of the light extraction structure 43 may be triangular to form a prism structure having a triangular cross-section, so that light emitted from the sub-pixel is deflected toward a direction of a center of the sub-pixel to improve the light emitting efficiency of the sub-pixel.

FIG. 7 is a schematic diagram of a cross-sectional structure of yet another display substrate according to an exemplary embodiment of the present disclosure, which illustrates a structure of four sub-pixels. As shown in FIG. 7, a main body structure of the display substrate of the present exemplary embodiment is substantially the same as the structure shown in FIG. 4 except that the light extraction structure of the present exemplary embodiment is a composite structure of convex lenses and prisms.

In an exemplary embodiment, the encapsulation structure layer 200 may include a first sublayer 41 provided on the display structure layer 100, a second sublayer 42 provided on a side of the first sublayer 41 away from the display structure layer, a plurality of light extraction structures 43 provided on a side of the second sublayer 42 away from the display structure layer, and a cover layer 44 for covering the plurality of light extraction structures 43. Positions of the plurality of light extraction structures 43 may have one-to-one correspondence to positions of the plurality of light filter layers 52. Light extraction structure 43 may be of a composite structure of convex lenses and prisms.

In an exemplary embodiment, the plurality of light extraction structures on the display substrate may be of different types. For example, the light extraction structure corresponding to the red sub-pixel may adopt a plano-convex convex lens structure, the light extraction structure corresponding to the blue sub-pixel may adopt a prism structure having a trapezoidal cross-section, and the light extraction structure corresponding to the green sub-pixel may adopt a prism structure having a triangular cross-section, so that different sub-pixels have different light emitting efficiency, thereby improving the display color gamut and further improving the display quality.

In an exemplary embodiment, in a plane parallel to the display structure layer, the plurality of light extraction structures on the display substrate may have a same shape, or may have different shapes, which is not limited here in the present disclosure.

Exemplary description is made below through a manufacturing process of a display substrate. A “patterning process” mentioned in the present disclosure includes photoresist coating, mask exposure, development, etching, photoresist stripping, etc., for a metal material, an inorganic material, or a transparent conductive material, and includes organic material coating, mask exposure, development, etc., for an organic material. Deposition may be any one or more of sputtering, evaporation, and chemical vapor deposition, coating may be any one or more of spray coating, spin coating, and inkjet printing, etching may be any one or more of dry etching and wet etching, and the present disclosure is not limited thereto. A “film” refers to a layer of film made of a certain material on a base substrate using deposition, coating, or other processes. If the “film” does not need to be processed through a patterning process in the entire manufacturing process, the “film” may also be called a “layer”. If the “film” needs to be processed through the patterning process in the entire manufacturing process, the “film” is called a “film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B.

In an exemplary embodiment, taking four sub-pixels in a display substrate as an example, a manufacturing process of the display substrate may include the following steps:
(1) Forming a base substrate and a pattern of a driving circuit layer. In an exemplary embodiment, forming the base substrate and the pattern of the driving circuit layer may include:

A silicon material is provided for forming a base substrate 10. The silicon material may be a semiconductor material such as monocrystalline silicon or polycrystalline silicon. For example, the silicon material may be a P-type silicon material, and the P-type silicon material may serve as a channel region of an N-type transistor. For another example, the silicon material may be an N-type silicon material, and the N-type silicon material may serve as a channel region of a P-type transistor.

Subsequently, a first insulation film and a polycrystalline silicon film are sequentially deposited on the base substrate 10, and the polycrystalline silicon film and the first insulation film are patterned by a patterning process to form a first insulation layer 11 and a polycrystalline silicon layer provided on the first insulation layer 11 on a silicon base substrate. Then, a doping process is carried out using a pattern of the polycrystalline silicon layer as a mask, a first conductive layer is formed from the doped polycrystalline silicon layer, a first region and a second region of an active layer are formed from the doped silicon base substrate, and a channel region is located between the first region and the second region. In an exemplary embodiment, the first conductive layer may include gate electrodes of a plurality of transistors.

Subsequently, a second insulation film is deposited, and the second insulation film is patterned by a patterning process to form a second insulation layer 12 for covering the pattern of the first conductive layer. A plurality of first via holes are provided on the second insulation layer 12.

Subsequently, a first metal film is deposited, and the first metal film is patterned by a patterning process to form a first metal layer on the second insulation layer 12. The first metal layer may at least include a scan signal line, and a first electrode and a second electrode of a transistor. The scan signal line is connected to a gate electrode of the transistor through a metal (such as tungsten) filled in the via hole, the first electrode of the transistor is connected to the first region of the active layer through the metal filled in the first via hole, and the second electrode of the transistor is connected to the second region of the active layer through the metal filled in the first via hole.

Then, a third insulation film is deposited, and the third insulation film is patterned by a patterning process to form a third insulation layer 13 for covering the pattern of the first metal layer. A plurality of second via holes are provided on the third insulation layer 13.

Subsequently, a second metal film is deposited, and the second metal film is patterned by the patterning process to form a second metal layer on the third insulation layer 13. The second metal layer may at least include a connection electrode connected to the second electrode of the transistor through a metal filled in the second via hole.

Subsequently, a fourth insulation film is deposited, and the fourth insulation film is patterned by a patterning process to form a fourth insulation layer 14 for covering the pattern of the second metal layer. A plurality of third via holes are provided on the fourth insulation layer 14.

So far, the pattern of the driving circuit layer 20 has been manufactured on the base substrate 10, as illustrated in FIG. 8. In an exemplary embodiment, the driving circuit layer 20 of each sub-pixel may include a plurality of transistors and a storage capacitor constituting the pixel driving circuit. In FIG. 8, only the pixel driving circuit including one transistor 20A is used as an example, and the transistor 20A may include an active layer, a gate electrode, a first electrode (a source electrode) and a second electrode (a drain electrode).

In an exemplary embodiment, the first insulation layer, the second insulation layer, and the third insulation layer may be made of any one or more of silicon oxide (SiOₓ), silicon nitride (SiNₓ), and silicon oxynitride (SiON), and each of them may be a single layer, a multilayer, or a composite layer. The first insulation layer may be referred to as a gate insulation (GI) layer, the second insulation layer may be referred to as an interlayer insulation (ILD) layer, and the third insulation layer may be referred to as a passivation (PVX) layer. The fourth insulation layer may be made of an organic material such as resin, and may be referred to as a flat layer.

The first metal layer and the second metal layer may be made of a metal material, such as any one or more of silver (Ag), copper (Cu), aluminum (Al), titanium (Ti) and molybdenum (Mo), or an alloy material of the aforementioned metals, such as an aluminum neodymium alloy (AlNd) or a molybdenum niobium alloy (MoNb), and each of them may be of a single-layered structure or a multi-layered composite structure, such as Ti/Al/Ti.

In an exemplary embodiment, the driving circuit layer 20 may further include a structure such as a power supply line, which is not limited here in the present disclosure.
(2) Forming a pattern of an anode conductive layer. In an exemplary embodiment, forming the pattern of the anode conductive layer may include depositing an anode conductive film on the base substrate on which the foregoing pattern is formed, and patterning the anode conductive film by a patterning process to form the pattern of the anode conductive layer. The pattern of the anode conductive layer at least includes an anode 31 located in each sub-pixel. The anode 31 is connected to a connection electrode through a metal filled in the third via hole, as shown in FIG. 9.

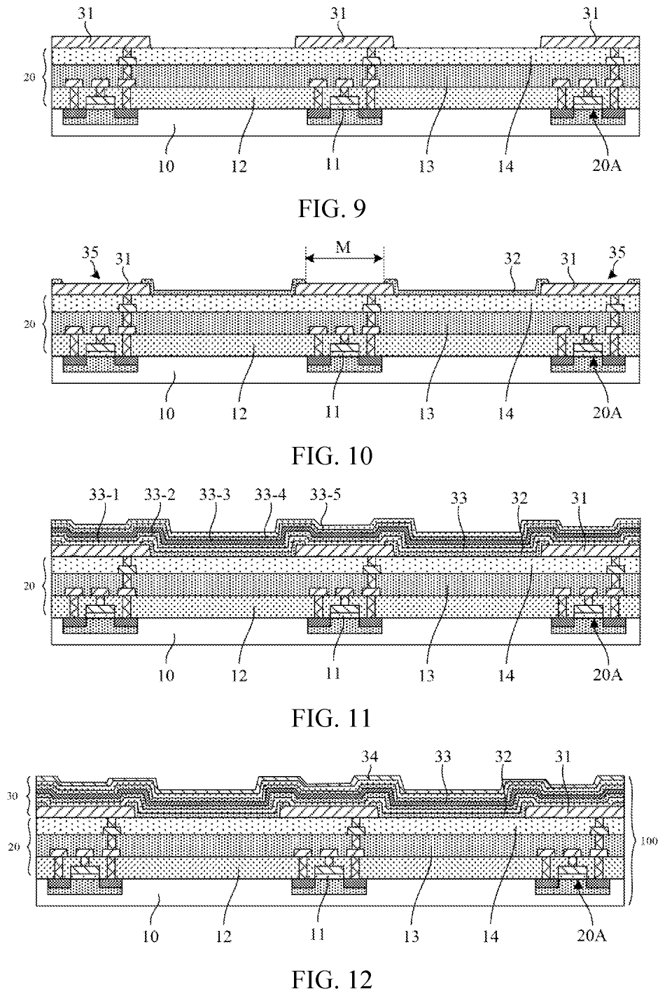

In an exemplary embodiment, the anode conductive layer may be made of a metal material or a transparent conductive material. The metal material may include any one or more of silver (Ag), copper (Cu), aluminum (Al), titanium (TI) and molybdenum (Mo), or an alloy material of the aforementioned metals. The transparent conductive material may include indium tin oxide (ITO) or indium zinc oxide (IZO). In an exemplary embodiment, the anode conductive layer may be of a single-layered structure or a multi-layered composite structure, such as ITO/AI/ITO.
(3) Forming a pattern of a pixel definition layer. In an exemplary embodiment, forming the pattern of the pixel definition layer may include depositing a pixel definition film on the base substrate on which the foregoing patterns are formed, and patterning the pixel definition film by a patterning process to form the pattern of the pixel definition layer 32, as shown in FIG. 10.

In an exemplary embodiment, a pixel opening 35 is provided on the pixel definition layer 32 of each sub-pixel, and the pixel definition layer in the pixel opening 35 is removed to expose a surface of the anode 31.

In an exemplary embodiment, in a plane parallel to the base substrate, a shape of the pixel opening 35 of each sub-pixel may include any one or more of a triangle, a square, a rectangle, a pentagon, a hexagon, a circle, and an ellipse. In a plane perpendicular to the base substrate, a cross-sectional shape of the pixel opening 35 of each sub-pixel may be an inverted trapezoidal shape, which is not limited here in the present disclosure.

In an exemplary embodiment, the pixel opening 35 within each sub-pixel has an opening width M, which may be about 2.4 μm to 2.8 μm. For example, the opening width M may be about 2.6 μm.

In an exemplary embodiment, the opening width M may be a maximum distance between any two points on an edge of the pixel opening 35. For example, for a pixel opening 35 having a shape of a circle, the opening width M is a diameter of the circle. For another example, for a pixel opening 35 having a shape of an ellipse, the opening width M is a long axis of the ellipse.

In an exemplary embodiment, the pixel definition layer may be made of any one or more of silicon oxide (SiOₓ), silicon nitride (SiNₓ), and silicon oxynitride (SiON), and may be a single layer, a multilayer, or a composite layer.
(4) Forming a pattern of an organic emitting layer. In an exemplary embodiment, forming the pattern of the organic light emitting layer may include forming the pattern of the organic light emitting layer 33 on the base substrate on which the foregoing patterns are formed using an evaporation process or an inkjet printing process. The organic light emitting layer 33 of each sub-pixel is connected to the anode 31 of the sub-pixel where the organic light emitting layer 33 is located through the pixel opening 35, as shown in FIG. 11.

In an exemplary embodiment, the organic light emitting layer 33 may include a plurality of light emitting sublayers connected in series to emit white light. For example, the organic light emitting layer 33 may include a first light emitting sublayer 33-1, a first charge generation layer 33-2, a second light emitting sublayer 33-3, a second charge generation layer 33-4 and a third light emitting sublayer 33-5 which are stacked. The first light emitting sublayer 33-1 is configured to emit first color light, the second light emitting sublayer 33-3 is configured to emit second color light, the third light emitting sublayer 33-5 is configured to emit third color light, and the first charge generation layer 33-2 and the second charge generation layer 33-4 are configured to transfer carriers.

In an exemplary embodiment, each light emitting sublayer may include a light emitting layer (EML), and any one or more of a hole injection layer (HIL), a hole transport layer (HTL), an electron-hole neutralization layer (EBL), a hole-hole neutralization layer (HBL), an electron transport layer (ETL), and an electron injection layer (EIL).

In an exemplary embodiment, the light emitting layer may include a host material and a dopant material doped into the host material. A doping ratio of the dopant material of the light emitting layer is 1% to 20%. Within a range of the doping ratio, on one hand, the host material of the light emitting layer may effectively transfer exciton energy to the dopant material of the light emitting layer to excite the dopant material of the light emitting layer to emit light; on the other hand, the host material of the light emitting layer “dilutes” the dopant material of the light emitting layer, so as to effectively improve collisions between molecules of the dopant material of the light emitting layer and fluorescence quenching caused by collisions between energies, and improve light emitting efficiency and device lifetime. In an exemplary embodiment, the doping ratio refers to a ratio of a mass of the dopant material to a mass of the light emitting layer, that is, a mass percentage. In an exemplary embodiment, the host material and the dopant material may be co-evaporated through a multi-source evaporation process, so that the host material and the dopant material are uniformly dispersed in the light emitting layer. The doping ratio may be adjusted and controlled by controlling an evaporation rate of the dopant material or by controlling a ratio of an evaporation rate of the host material to the evaporation rate of the dopant material in the evaporation process. In an exemplary embodiment, a thickness of the light emitting layer may be about 10 nm to 50 nm.

In an exemplary embodiment, the hole injection layer may be made of an inorganic oxide, such as molybdenum oxide, titanium oxide, vanadium oxide, rhenium oxide, ruthenium oxide, chromium oxide, zirconium oxide, hafnium oxide, tantalum oxide, silver oxide, tungsten oxide, or manganese oxide, or may be made of a p-type dopant of a strong electron-withdrawing system and a dopant of a hole transport material. In an exemplary embodiment, a thickness of the hole injection layer may be about 5 nm to 20 nm.

In an exemplary embodiment, the hole transport layer may be made of a material with higher hole mobility, such as an aromatic amine compound, a substituent group of which may be carbazole, methylfluorene, spirofluorene, dibenzothiophene or furan. In an exemplary embodiment, a thickness of the hole transport layer may be about 40 nm to 150 nm.

In an exemplary embodiment, the hole-hole neutralization layer and the electron transport layer may be made of an aromatic heterocyclic compound, such as an imidazole derivative such as a benzimidazole derivative, an imidazopyridine derivative, and a benzimidazophenanthridine derivative; an azine derivative such as a pyrimidine derivative, and a triazine derivative; a compound including a nitrogen-containing six-membered ring structure (also including a compound having a substituent group of a phosphine oxide system on a heterocyclic ring) such as a quinoline derivative, an isoquinoline derivative, and a phenanthroline derivative. In an exemplary embodiment, a thickness of the hole-hole neutralization layer may be about 5 nm to 15 nm, and a thickness of the electron transport layer may be about 20 nm to 50 nm.

In an exemplary embodiment, the electron injection layer may be made of an alkali metal or a metal material, such as lithium fluoride (LiF), ytterbium (Yb), magnesium (Mg), or calcium (Ca), or a compound of these alkali metals or metals. In an exemplary embodiment, a thickness of the electron injection layer may be about 0.5 nm to 2 nm.

In some possible embodiments, the organic light emitting layer may adopt an organic light emitting layer emitting light of a first color and an organic light emitting layer emitting complementary light of the light of the first color, and the two organic light emitting layers are sequentially stacked so as to emit white light as a whole, which is not limited here in the present disclosure.

In an exemplary embodiment, the organic emitting layer may include a microcavity adjustment layer, so that a thickness of the organic emitting layer between a cathode and an anode satisfies a design of a length of a microcavity. In some exemplary embodiments, the hole transport layer, the electron block layer, the hole block layer, or the electron transport layer may be used as the microcavity adjustment layer, which is not limited here in the present disclosure.
(5) Forming a pattern of a cathode. In an exemplary embodiment, forming the pattern of the cathode may include forming the pattern of the cathode 34 by evaporation or deposition or the like. The cathode 34 is provided on a side of the organic light emitting layer 33 away from the base substrate, as shown in FIG. 12.

In an exemplary embodiment, the cathode may be made of a metal material or a transparent conductive material. The metal material may include any one or more of magnesium (Mg), silver (Ag), aluminum (Al), copper (Cu), and lithium (Li), or an alloy material of the aforementioned metals, and the transparent conductive material may include indium zinc oxide (IZO). In an exemplary embodiment, the cathode may be of a single-layered structure or a multi-layered composite structure, such as Mg/Ag.

In an exemplary embodiment, a pattern of an optical coupling layer may be formed after the pattern of the cathode is formed. The optical coupling layer is provided on the cathode. A refractive index of the optical coupling layer may be greater than a refractive index of the cathode, which facilitates light extraction and increases light emitting efficiency. The optical coupling layer may be made of an organic material, or an inorganic material, or both, and may be a single layer, a multi-layer, or a composite layer, which is not limited here in the present disclosure.

So far, the pattern of the light emitting structure layer 30 has been manufactured on the driving circuit layer 20. The light emitting structure layer 30 may include the anode 31, the pixel definition layer 32, the organic light emitting layer 33, and the cathode 34. The organic light emitting layer 33 emits light under the drive of the anode 31 and the cathode 34.

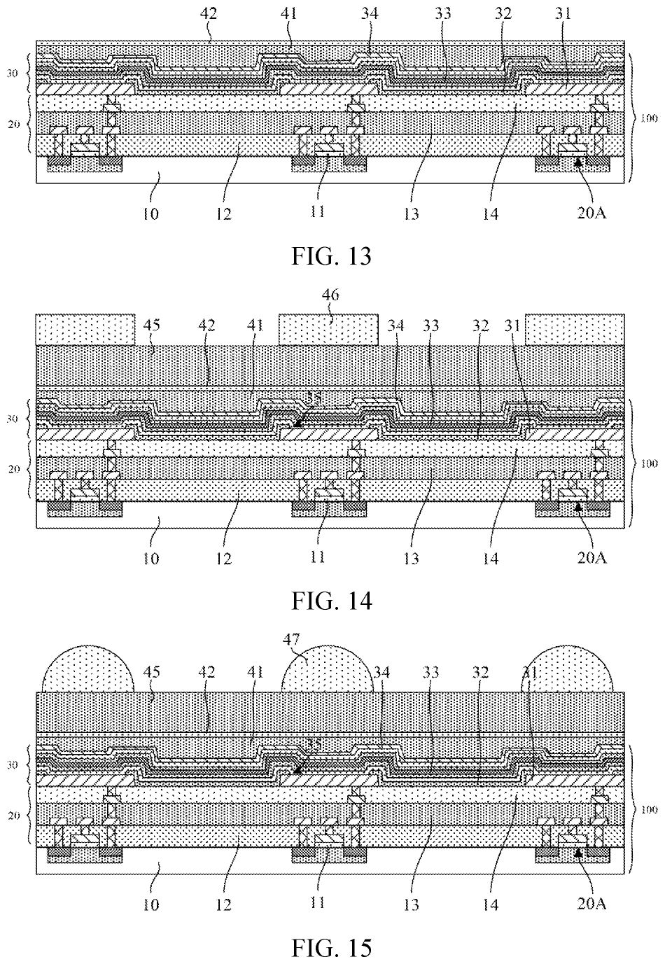

In an exemplary embodiment, the base substrate 10, the driving circuit layer 20 provided on the base substrate 10 and the light emitting structure layer 30 provided on the driving circuit layer 20 constitute a display structure layer 100.
(6) Forming patterns of a first sublayer and a second sublayer. In an exemplary embodiment, forming the patterns of the first sublayer and the second sublayer may include sequentially depositing a first inorganic material film and a second inorganic material film on the base substrate on which the foregoing patterns are formed, to form the first sublayer 41 for covering the cathode 34 and the second sublayer 42 provided on the first sublayer 41, as shown in FIG. 13.

In an exemplary embodiment, a material for the first sublayer 41 may include silicon nitride (SiNₓ), which may be deposited in a chemical vapor deposition (CVD) manner or in a plasma enhanced chemical vapor deposition (PECVD) manner.

In an exemplary embodiment, a thickness of the first electrode 41 may be about 0.8 μm to 1.2 μm. For example, the thickness of the first sublayer 41 may be about 1.0 μm.

In an exemplary embodiment, a material for the second sublayer 42 may include alumina (Al₂O₃), which may be deposited in an atomic layer deposition (ALD) manner, and a deposition temperature may be about 85° C. to 95° C. For example, the deposition temperature may be about 90° C.

In an exemplary embodiment, a thickness of the second sublayer 42 may be about 0.03 μm to 0.05 μm. For example, the thickness of the second sublayer 42 may be about 0.05 μm.
(7) Forming a pattern of a third sublayer. In an exemplary embodiment, forming the pattern of the third sublayer may include depositing a third inorganic material film 45 on the second sublayer 42 on the base substrate on which the foregoing patterns are formed, coating a layer of photoresist (PR) on the third inorganic material film, and then exposing the photoresist using a mask, and developing to form a photoresist pattern, as shown in FIG. 14.

In an exemplary embodiment, a material for the third inorganic material film 45 may include silicon nitride (SiNₓ), which may be deposited in a chemical vapor deposition (CVD) manner or a plasma enhanced chemical vapor deposition (PECVD) manner.

In an exemplary embodiment, a thickness of the third inorganic material film 45 may be about 2.0 μm to 2.4 μm. For example, the thickness of the third inorganic material film 45 may be about 2.2 μm.

In an exemplary embodiment, the photoresist pattern may include a plurality of photoresist columns 46 having a rectangular or trapezoidal cross-sectional shape. An orthographic projection of the pixel opening 35 on the base substrate may be within a range of an orthographic projection of a photoresist column 46 on the base substrate, that is, an area of the photoresist column 46 is greater than an area of the pixel opening 35.
(8) Forming a photoresist etching pattern. In an exemplary embodiment, forming the photoresist etching pattern may include thermally melting a photoresist column 46 into a hemispherical shape through a baking process on the base substrate on which the foregoing patterns are formed, to form the photoresist etching pattern, as shown in FIG. 15.

In an exemplary embodiment, the photoresist etching pattern may include a plurality of photoresist spherical crown bodies 47 having a semicircular cross-sectional shape. The orthographic projection of the pixel opening 35 on the base substrate may be within a range of an orthographic projection of a photoresist spherical crown body 47 on the base substrate, that is, an area of the photoresist spherical crown body 47 is greater than the area of the pixel opening 35.

In an exemplary embodiment, a baking temperature of the baking process may be about 100° C. to 120° C., and a baking time may be about 250 seconds to 350 seconds. For example, the baking temperature may be about 110° C. and the baking time may be about 300 seconds.

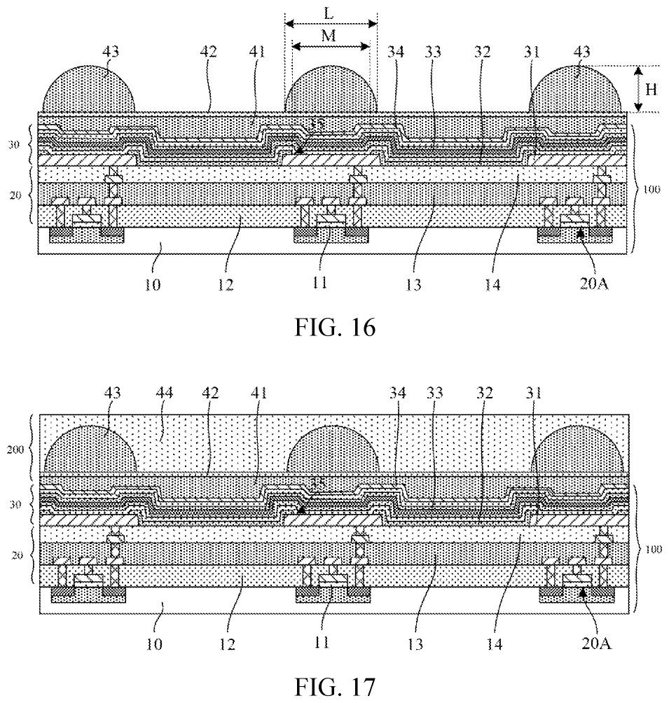

In an exemplary embodiment, the photoresist may be a positive photoresist with a certain cohesive force. By baking, a structure of the positive photoresist may be redistributed driven by internal energy, to finally form a hemispherical lens morphology.
(9) Forming a pattern of a light extraction structure. In an exemplary embodiment, forming the pattern of the light extraction structure may include etching the third inorganic material film by an etching process on the base substrate on which the foregoing patterns are formed, transferring a topography of the photoresist etching pattern onto the third inorganic material film, and peeling off the remaining photoresist, to form the pattern of the light extraction structure on the second sublayer 42, as shown in FIG. 16.

In an exemplary embodiment, the pattern of the light extraction structure may include a plurality of light extraction structures 43 configured to converge light emitted from sub-pixels. A light extraction structure 43 may be a spherical crown body, which forms a plano-convex convex lens having a lower flat surface and an upper convex surface (i.e., the lower surface is flat and the upper surface is convex) to deflect light emitted from the sub-pixel toward a direction of a center of the sub-pixel so as to improve the light emitting efficiency of the sub-pixel.

In an exemplary embodiment, the orthographic projection of the pixel opening 35 on the base substrate may be within a range of an orthographic projection of the light extraction structure 43 on the base substrate.

In an exemplary embodiment, on a plane parallel to the base substrate, a shape of the light extraction structure 43 may include any one or more of a triangle, a square, a rectangle, a pentagon, a hexagon, a circle, and an ellipse.

In an exemplary embodiment, a light extraction area of the light extraction structure 43 may be 1.4 times to 1.6 times an opening area of the pixel opening 35 to satisfy the maximum light efficiency gain. The light extraction area may be an area of the orthographic projection of the light extraction structure 43 on the display substrate, and the opening area may be an area of the orthographic projection of the pixel opening 35 on the display substrate. For example, the light extraction area=1.5*opening area.

In an exemplary embodiment, a light extraction width L of the light extraction structure 43 may be about 3.2 μm to 3.4 μm. For example, the light extraction width L may be about 3.2 μm.

In an exemplary embodiment, the light extraction width L of the light extraction structure 43 may be a maximum width of the light extraction structure 43, i.e., a maximum distance between any two points on an edge of the light extraction structure 43.

In an exemplary embodiment, the light extraction structure 43 has a light extraction height H which may be about 2.0 μm to 2.2 μm. For example, the light extraction height H may be about 2.1 μm.

In an exemplary embodiment, a refractive index of the light extraction structure 43 may be about 1.92 to 2.2. For example, the refractive index of the light extraction structure 43 may be about 2.0.

In an exemplary embodiment, the etching process may employ a dry etching process that ultimately transfers the topography of the photoresist etching pattern onto the third inorganic material film by adjusting a ratio of an etching rate of the photoresist to an etching rate of the third inorganic material film.
(10) Forming a pattern of a cover layer. In an exemplary embodiment, forming the pattern of the cover layer may include coating an organic material film on the base substrate on which the foregoing patterns are formed to form the pattern of the cover layer 44 for covering the plurality of light extraction structures 43, as shown in FIG. 17.

In an exemplary embodiment, a material for the cover layer 44 may be an organic material. For example, the material for the cover layer 44 may be an optical resin.

In an exemplary embodiment, a thickness of the cover layer 44 may be greater than the light extraction height of the light extraction structure 43, and a difference between the thickness of the cover layer 44 and the light extraction height of the light extraction structure 43 may be greater than or equal to 0.2 μm.

In an exemplary embodiment, a refractive index of the cover layer 44 may be less than or equal to 1.5. For example, the refractive index of the cover layer 44 may be about 1.45.

In an exemplary embodiment, a transmittance of the cover layer 44 is greater than 95% in a wavelength band from 380 nm to 980 nm.

So far, the encapsulation structure layer 200 has been manufactured on the display structure layer 100. The encapsulation structure layer 200 may include the first sublayer 41, the second sublayer 42 provided on a side of the first sublayer 41 away from the display structure layer, the plurality of light extraction structures 43 provided on a side of the second sublayer 42 away from the display structure layer, and the cover layer 44 for covering the plurality of light extraction structures 43. A high refractive index material of the light extraction structure and a low refractive index material of the cover layer form a condensing effect, which may not only meet the optical requirements, but also ensure the encapsulation characteristics, thereby realizing the integration of encapsulation and light emission.
(11) Forming a pattern of a color film structure layer. In an exemplary embodiment, forming the pattern of the color filter structure layer may include:

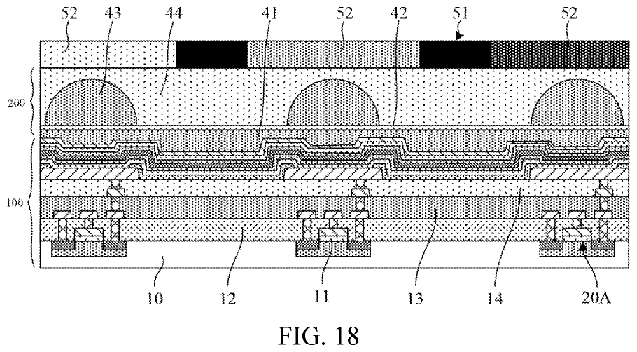

A black matrix film is first coated on the base substrate on which the foregoing patterns are formed, and then the black matrix film is patterned by a patterning process to form a pattern of the black matrix (BM), which may at least include a plurality of black matrices 51. The plurality of black matrices 51 may be provided at intervals, and light-transmitting openings are formed between adjacent black matrices. Subsequently, a red filter film, a blue filter film, and a green filter film are sequentially coated, and the red filter film, the blue filter film, and the green filter film are patterned by a patterning process, respectively, to form a plurality of light filter layers (CF) 52 in the light-transmitting openings formed in the black matrices 51, respectively, thereby finishing the manufacturing of the pattern of the color film structure layer, as shown in FIG. 18.

In an exemplary embodiment, an orthographic projection of at least one light extraction structure 43 on the display structure layer at least partially overlaps an orthographic projection of at least one light filter layer 52 on the display structure layer.

In an exemplary embodiment, the orthographic projection of the at least one light extraction structure 43 on the display structure layer may be within a range of the orthographic projection of the at least one light filter layer 52 on the display structure layer.

In an exemplary embodiment, the orthographic projection of the at least one light extraction structure 43 on the display structure layer may substantially coincide with the orthographic projection of the at least one light filter layer 52 on the display structure layer.

In an exemplary embodiment, an orthographic projection of a light extraction structure 43 on the display structure layer does not overlap an orthographic projection of a black matrix 51 on the display structure layer.

In an exemplary embodiment, a pattern of a touch structure layer may be formed before the color film layer is formed, which is not limited here in the present disclosure.

Subsequent manufacturing may include bonding a cover plate and other processes, which will not be repeated here.

As can be seen from the structure and the manufacturing process of the display substrate of the exemplary embodiment of the present disclosure, the present disclosure may effectively improve the light emitting efficiency by providing a light extraction structure in the display substrate, so that the light emitted from the display structure layer is deflected in the direction of the center of the sub-pixel. In the present disclosure, the light extraction structure is provided on a side of the color film structure layer close to the display structure layer, so that the light emitted from the display structure layer is modulated by the light extraction structure first and then passes through the color film structure layer. Compared with the display substrate in which the light first passes through the color film structure layer and then reaches the light extraction structure, the path of the light emitted from the display structure layer to the light extraction structure is shorter in the present disclosure, which may further improve the light emitting efficiency, improve the light emission color gamut and improve the display quality. By providing the light extraction structure in the encapsulation structure layer, the present disclosure realizes the integration of encapsulation and light emission, which may effectively reduce a thickness of the display substrate, facilitate the realization of thinness and improve the competitiveness of products. By synchronously manufacturing the light extraction structure when manufacturing the encapsulation structure layer, the present disclosure may reduce the manufacturing process, shorten the process time, improve the production efficiency and reduce the production cost. The manufacturing method of the present disclosure does not need to change the process flow for manufacturing the encapsulation structure layer, nor does it need to change the process equipment for manufacturing the encapsulation structure layer. It has little improvement on the process of manufacturing the encapsulation structure layer, thus it may be well compatible with the manufacturing process of the encapsulation structure layer, and be highly realizable and practicable.

The structure and manufacturing process in the exemplary embodiments of the present disclosure are merely illustrative. In practical implementation, a corresponding structure may be changed and patterning processes may be increased or decreased according to actual needs, which is not limited here in the present disclosure.

An embodiment of the present disclosure further provides a manufacturing method for a display substrate to manufacture the display substrate of the foregoing exemplary embodiments. In an exemplary embodiment, the manufacturing method may include:
forming a display structure layer;
forming an encapsulation structure layer on the display structure layer, the encapsulation structure layer at least including a light extraction structure for improving light emitting efficiency; and
forming a color film structure layer on the encapsulation structure layer.

The present disclosure further provides a display device including the aforementioned display substrate. The display device may be any product or component with a display function, such as a mobile phone, a tablet computer, a television, a display, a laptop computer, a digital photo frame, and a navigator, which is not limited here in the present disclosure.

Although the implementations of the present disclosure are disclosed above, the contents are only implementations used for ease of understanding of the present disclosure, but not intended to limit the present disclosure. Any person skilled in the art to which the present disclosure pertains may make any modification and variation in implementation forms and details without departing from the spirit and scope disclosed in the present disclosure. However, the scope of patent protection of the present disclosure is still subject to the scope defined by the appended claims.

1. A display substrate, comprising a display structure layer, an encapsulation structure layer provided on the display structure layer, and a color film structure layer provided on a side of the encapsulation structure layer away from the display structure layer, wherein the encapsulation structure layer at least comprises a light extraction structure for improving light emitting efficiency.

2. The display substrate according to claim 1, wherein, the display structure layer at least comprises a base substrate, a driving circuit layer provided on the base substrate, and a light emitting structure layer provided on a side of the driving circuit layer away from the base substrate, wherein the light emitting structure layer at least comprises an anode and a pixel definition layer provided on a side of the anode away from the base substrate, a pixel opening is provided on the pixel definition layer, the pixel opening exposes the anode, and an orthographic projection of the pixel opening on the base substrate is within a range of an orthographic projection of the light extraction structure on the base substrate.

3. The display substrate according to claim 2, wherein, a light extraction area of the light extraction structure is 1.4 times to 1.6 times an opening area of the pixel opening, the light extraction area is an area of an orthographic projection of the light extraction structure on the display substrate, and the opening area is an area of an orthographic projection of the pixel opening on the display substrate.

4. The display substrate according to claim 1, wherein, the encapsulation structure layer at least comprises a first sublayer, a second sublayer provided on a side of the first sublayer away from the display structure layer, a plurality of light extraction structures provided on a side of the second sublayer away from the display structure layer, and a cover layer for covering the plurality of light extraction structures, wherein a refractive index of the light extraction structure is greater than a refractive index of the cover layer.

5. The display substrate according to claim 4, wherein, a material for the first sublayer comprises silicon nitride, and a thickness of the first sublayer is 0.8 μm to 1.2 μm.

6. The display substrate according to claim 4, wherein, a material for the second sublayer comprises alumina, and a thickness of the second sublayer is 0.03 μm to 0.05 μm.

7. The display substrate according to claim 4, wherein, the refractive index of the light extraction structure is greater than 1.92, and the refractive index of the cover layer is less than or equal to 1.5.

8. The display substrate according to claim 4, wherein, a transmittance of the cover layer is greater than 95% in a wavelength band from 380 nm to 980 nm.

9. The display substrate according to claim 1, wherein, the light extraction structure comprises any one or more of a plano-convex convex lens, a prism with a trapezoidal cross-section, or a prism with a triangular cross-section.

10. The display substrate according to claim 1, wherein, on a plane parallel to the display substrate, a light extraction width of the light extraction structure is 3.2 μm to 3.4 μm, and the light extraction width is a maximum distance between any two points on an edge of the light extraction structure.

11. The display substrate according to claim 1, wherein, a light extraction height of the light extraction structure is 2.0 μm to 2.2 μm, and the light extraction height is a maximum distance between a surface on a side of the light extraction structure away from the display structure layer and a surface on a side of the light extraction structure close to the display structure layer.

12. The display substrate according to claim 11, wherein, the cover layer is an organic material, and a difference between a thickness of the cover layer and the light extraction height is greater than or equal to 0.2 μm.

13. The display substrate according to claim 1, wherein, the color film structure layer at least comprises a plurality of light filter layers and black matrices provided between the light filter layers, and an orthographic projection of the light extraction structure on a display substrate plane is within a range of an orthographic projection of a light filter layer on the display substrate plane.

14. A display device, comprising the display substrate according to claim 1.

15. A method for manufacturing a display substrate, comprising:
forming a display structure layer,
forming an encapsulation structure layer on the display structure layer, wherein the encapsulation structure layer at least comprises a light extraction structure for improving light emitting efficiency; and
forming a color film structure layer on the encapsulation structure layer.
